(19) United States
(12) Patent Application Publication
(10) Pub. No.: US 2026/0052754 A1
(43) Pub. Date: Feb. 19, 2026

(54) TRANSISTOR BILAYER DIELECTRIC WALL

(71) Applicant: Applied Materials, Inc., Santa Clara, CA (US)

(72) Inventors: Sai Hooi Yeong, Cupertino, CA (US); Gregory Costrini, Flanders, NJ (US); Ashish Pal, San Ramon, CA (US); Pratik B. Vyas, Fremont, CA (US); Prasad Bhosale, San Jose, CA (US); Veeraraghavan S. Basker, Fremont, CA (US); El Mehdi Bazizi, San Jose, CA (US); Benjamin Colombeau, San Jose, CA (US); Balasubramanian Pranatharthiharan, San Jose, CA (US)

(73) Assignee: Applied Materials, Inc., Santa Clara, CA (US)

(21) Appl. No.: 19/291,818

(22) Filed: Aug. 6, 2025

Related U.S. Application Data
(60) Provisional application No. 63/683,894, filed on Aug. 16, 2024.
(60) Provisional application No. 63/727,775, filed on Dec. 4, 2024.

(51) Int. Cl. H10D 84/01; H10D 84/85

(52) U.S. Cl. CPC H10D 84/0188; H10D 84/017; H10D 84/851

(57) ABSTRACT

Described are semiconductor devices, e.g., GAA, FinFET, CFET, having a bilayer dielectric wall. Methods of forming a semiconductor device form a bilayer dielectric wall during the formation of the shallow trench isolation (STI). The first or liner dielectric layer of the bilayer dielectric wall is designed to allow the second or core dielectric layer to withstand downstream etching and to be removed prior to formation of the source/drain epitaxial regions. In some embodiments, the core dielectric layer is removed to form an airgap, mitigating the performance penalty associated with the bilayer dielectric wall.

### CROSS-REFERENCE TO RELATED APPLICATIONS

This application claims priority to U.S. Provisional Application No. 63/727,775, filed Dec. 4, 2024 and to U.S. Provisional Application No. 63/683,894, filed Aug. 16, 2024, the entire disclosures of which are hereby incorporated by reference herein.

### TECHNICAL FIELD

Embodiments of the present disclosure generally relate to semiconductor devices and, more particularly, to transistors, e.g., gate-all-around devices (GAA), field-effect transistors (FinFETs), and complementary field effect transistors (CFETs), having dielectric walls for cell scaling and methods of manufacture.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETs, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, a complementary field effect transistor (CFET) structure, and a gate all around (GAA) structure. Logic gate performance is related to the characteristics of the materials used as well as the thickness and area of the structural layers. As some gate characteristics are adjusted to accommodate device scaling, however, challenges arise.

As device sizes continue to reduce, film characteristics may lead to larger impacts on device performance. As devices shrink and more complex patterning schemes are utilized in the industry, deposition of thin films becomes a challenge. In addition, as material thicknesses continue to reduce, as-deposited characteristics of the films may have a greater impact on device performance. These challenges include depositing seam free and/or void free films in high aspect ratio features.

Thus, there is a need in the art for logic devices and methods of manufacture which permit further active spacing scaling.

### SUMMARY

One or more embodiments of the disclosure are directed to methods of forming a semiconductor device. In one or more embodiments, a method of forming a semiconductor device comprises: forming a bilayer dielectric wall in an opening between one or more first channel regions for a first transistor and one or more second channel regions for a second transistor.

Further embodiments of the disclosure are directed to methods of forming a semiconductor device. In one or more embodiments, a method of forming a semiconductor device comprises: depositing a first dielectric layer between a first superlattice structure and on a second superlattice structure on a top surface of a substrate, the first superlattice structure and the second superlattice structure comprising a plurality of horizontal channel layers and a corresponding plurality of semiconductor material layers alternatingly arranged in a plurality of stacked pairs and separated by an opening; depositing a second dielectric layer on the first dielectric layer to form a bilayer dielectric wall; recessing the second dielectric layer to expose a surface of the first dielectric layer and leave a recessed portion of the second dielectric layer in the opening between the first superlattice structure and the second superlattice structure; and encapsulating the recessed portion of the second dielectric layer to form an encapsulated bilayer dielectric wall between the first superlattice structure and the second superlattice structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a semiconductor device in accordance with some embodiments of the present disclosure;

FIG. 2A illustrates a cross-sectional view of a semiconductor device according to one or more embodiments of the present disclosure;

FIG. 2B illustrates a cross-sectional view of an exemplary semiconductor device according to one or more embodiments of the present disclosure;

FIG. 2C illustrates a cross-sectional view of an exemplary semiconductor device according to one or more embodiments of the present disclosure;

FIG. 2D illustrates a cross-sectional view of an exemplary semiconductor device according to one or more embodiments of the present disclosure;

FIG. 2E illustrates a cross-sectional view of an exemplary semiconductor device according to one or more embodiments of the present disclosure;

FIG. 2F illustrates a cross-sectional view of an exemplary semiconductor device according to one or more embodiments of the present disclosure;

FIG. 2G illustrates a cross-sectional view of an exemplary semiconductor device according to one or more embodiments of the present disclosure;

FIG. 2H illustrates a cross-sectional view of an exemplary semiconductor device according to one or more embodiments of the present disclosure;

FIG. 2I illustrates a cross-sectional view of an exemplary semiconductor device according to one or more embodiments of the present disclosure;

FIG. 2J illustrates a cross-sectional view of an exemplary semiconductor device according to one or more embodiments of the present disclosure;

FIG. 2K illustrates a cross-sectional view of an exemplary semiconductor device according to one or more embodiments of the present disclosure;

FIG. 2L illustrates a cross-sectional view of an exemplary semiconductor device according to one or more embodiments of the present disclosure;

FIG. 2M illustrates a cross-sectional view of an exemplary semiconductor device according to one or more embodiments of the present disclosure;

FIG. 2N illustrates a cross-sectional view of an exemplary semiconductor device according to one or more embodiments of the present disclosure;

FIG. 2O illustrates a cross-sectional view of an exemplary semiconductor device according to one or more embodiments of the present disclosure;

FIG. 2P illustrates a cross-sectional view of an exemplary semiconductor device according to one or more embodiments of the present disclosure;

FIG. 2Q illustrates a cross-sectional view of an exemplary semiconductor device according to one or more embodiments of the present disclosure;

FIG. 2R illustrates a cross-sectional view of an exemplary semiconductor device according to one or more embodiments of the present disclosure;

FIG. 2S illustrates a cross-sectional view of an exemplary semiconductor device according to one or more embodiments of the present disclosure;

FIG. 2T illustrates a cross-sectional view of an exemplary semiconductor device according to one or more embodiments of the present disclosure;

FIG. 2U illustrates a cross-sectional view of an exemplary semiconductor device according to one or more embodiments of the present disclosure;

FIG. 2V illustrates a cross-sectional view of an exemplary semiconductor device according to one or more embodiments of the present disclosure;

FIG. 2W illustrates a cross-sectional view of an exemplary semiconductor device according to one or more embodiments of the present disclosure;

FIG. 2X illustrates a cross-sectional view of an exemplary semiconductor device according to one or more embodiments of the present disclosure;

FIG. 2Y illustrates a cross-sectional view of an exemplary semiconductor device according to one or more embodiments of the present disclosure;

FIG. 2Z illustrates a cross-sectional view of an exemplary semiconductor device according to one or more embodiments of the present disclosure;

FIG. 2AA illustrates a cross-sectional view of an exemplary semiconductor device according to one or more embodiments of the present disclosure;

FIG. 2BB illustrates a cross-sectional view of an exemplary semiconductor device according to one or more embodiments of the present disclosure;

FIG. 2CC illustrates a cross-sectional view of an exemplary semiconductor device according to one or more embodiments of the present disclosure;

FIG. 2DD illustrates a cross-sectional view of an exemplary semiconductor device according to one or more embodiments of the present disclosure;

FIG. 3A illustrates a cross-sectional views of an exemplary semiconductor structure according to one or more embodiments of the present disclosure;

FIG. 3B illustrates a cross-sectional views of an exemplary semiconductor structure according to one or more embodiments of the present disclosure;

FIG. 3C illustrates a cross-sectional views of an exemplary semiconductor structure according to one or more embodiments of the present disclosure;

FIG. 3D illustrates a cross-sectional views of an exemplary semiconductor structure according to one or more embodiments of the present disclosure;

FIG. 3E illustrates a cross-sectional views of an exemplary semiconductor structure according to one or more embodiments of the present disclosure; and

FIG. 4 illustrates a schematic top-view diagram of an example multi-chamber processing system according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor”, “reactant”, “reactive gas”, and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, entering the channel at the source (S) is designated Is and current entering the channel at the drain (D) is designated I_{D}. Drain-to-source voltage is designated Vos. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is a n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate-all-around (GAA)” or “gate-all-around transistor” is used to refer to an electronic device, e.g., a transistor, in which the gate material surrounds the channel region on all sides. The channel region of a GAA transistor may include nanowires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One example of gate-all-around (GAA) technology is complementary field effect transistor (CFET). As used herein, the term “complementary field-effect transistor (CFET)” refers to a transistor that includes NMOS FET devices and PMOS FET devices stacked on each other. Each of the NMOS FET devices and the PMOS FET devices that form the CFET are GAA transistors or hGAA transistors. CFET transistors have increased on-chip device density and reduced area consumption when compared to GAA transistors.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

The current generation of advanced logic devices are quasi-planar architecture gate-all-around (GAA) devices that have evolved from FinFET technology. GAA devices enable area scaling in several ways by essentially stacking the fin vertically. Arranging the fins horizontally in the nanosheet stack reduces the cell height by several fin pitches. This reduces the footprint of the GAA device relative to FinFET and also enables better gate control and device performance. Since the gate pitch is no longer scaling, additional cell area/height scaling requires reducing the space between the nanosheet stacks.

The challenge in reducing the space separating the GAA nanosheet stacks is that the epitaxial source/drain dimensions are not scaling by the requisite amount to achieve the desired cell scaling. To allow reduction of the nanosheet stack spacing, a dielectric wall has been implemented at the N3 node technology. The dielectric wall allows the FinFET or GAA devices to be placed closer together without shorting the source/drain epitaxial material. In addition, the dielectric wall improves the RMG WFM process by allowing more lateral etch for removal of the metal films without affecting adjacent devices.

Unfortunately, the dielectric wall imposes a performance penalty. There are only a few dielectric materials that can survive the device fabrication process sequence, and these have a high dielectric constant. Low-K materials will not survive the fabrication sequence. Further cell scaling with a dielectric wall requires a different approach to provide the functional capability with minimal performance penalty.

In one or more embodiments, a horizontal gate-all-around (hGAA) or gate-all-around (GAA) transistor comprises a substrate having a top surface; a source region having a source and a source contact, the source region on the top surface of the substrate; a drain region having a drain and a drain contact, the drain region on the top surface of the substrate; a channel located between the source and the drain and having an axis that is substantially parallel to the top surface of the substrate; a gate enclosing the channel between the source region and the drain region; a bilayer dielectric wall placed between the nMOS and pMOS devices, overlying and in contact with one or more of the gate, the source contact, or the drain contact, and a gate spacer overlying the gate. Other embodiments may place a dielectric wall between nMOS devices and pMOS devices at the library cell boundary.

One or more embodiments of the disclosure are directed to methods of forming semiconductor devices, such as gate-all-around devices, FinFETs, and CFETs. In the method of one or more embodiments, gate-all-around transistors are fabricated using a standard process flow. Some embodiments advantageously provide methods that form a bilayer dielectric wall during the formation of the shallow trench isolation (STI). In one or more embodiments, a method of manufacturing a semiconductor device is advantageously provided where a bilayer dielectric wall is formed. The outer layer of the bilayer dielectric wall is designed to allow the inner dielectric wall to withstand downstream etching and to be removed prior to formation of the source/drain epitaxial regions.

In one or more embodiments, a bilayer dielectric wall is composed of a core material of a high-κ material that is contained within an outer layer of a low-K material. The bilayer implementation provides two significant features that permit scaling of the space between the nanosheets while allowing space for the epitaxial source/drains.

The method of one of more embodiments proposes to remove the outer layer of the dielectric wall, prior to the source/drain epi, which opens space for the epi source/drains. In this way, a dielectric wall of sufficient dimension and material composition to survive the device processing is advantageously enabled, and then a portion is removed when it is no longer needed to provide space for the epi SD.

One or more embodiments also provide a method for removing the high-κ core material from the backside of the wafer following completion of the frontside processing to form an airgap. In this way, a significant parasitic reduction is advantageously enabled that will mitigate the performance penalty associated with the dielectric wall at advanced technology nodes.

Although the disclosure will routinely identify specific gate-all-around (GAA) devices, and components thereof, it will be readily understood that the device and methods are equally applicable to other field-effect transistors (e.g., FinFETS and CFETs), orientations thereof, as processes for forming such devices. Accordingly, the technology should not be considered to be so limited as for use with these specific devices or methods alone. The disclosure will discuss one possible semiconductor device that may include one or more components, utilizing one or more a bilayer dielectric wall according to embodiments of the present technology before additional variations and adjustments to this apparatus according to embodiments of the present technology are described.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

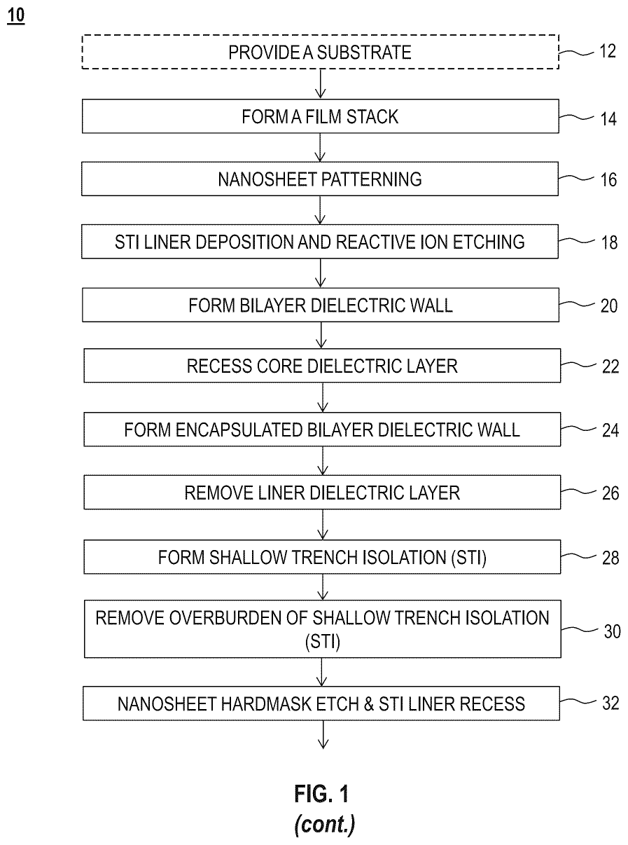

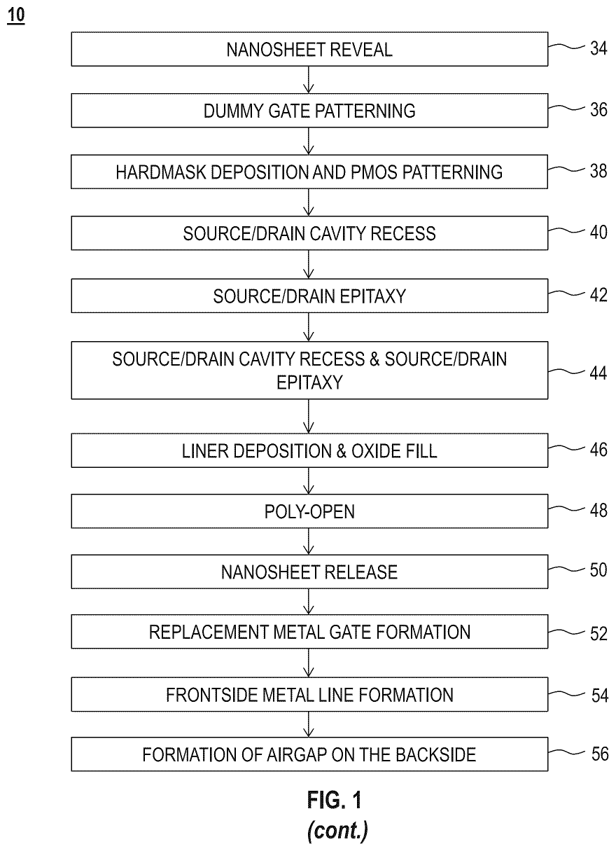

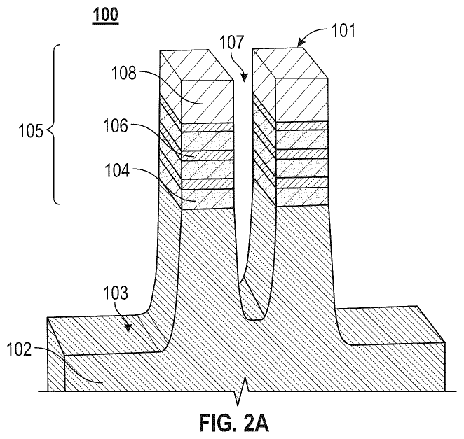

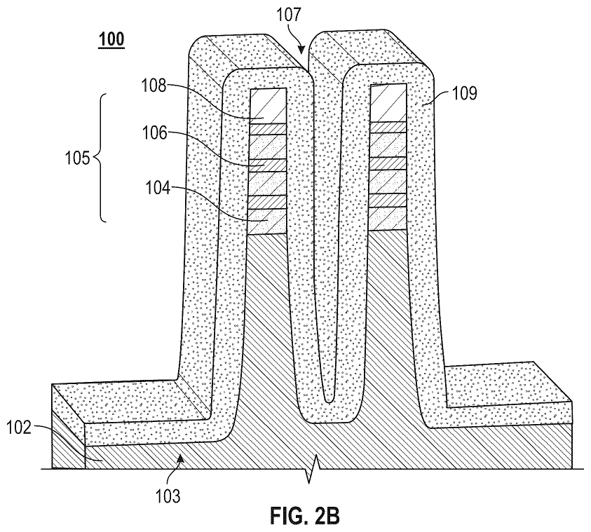

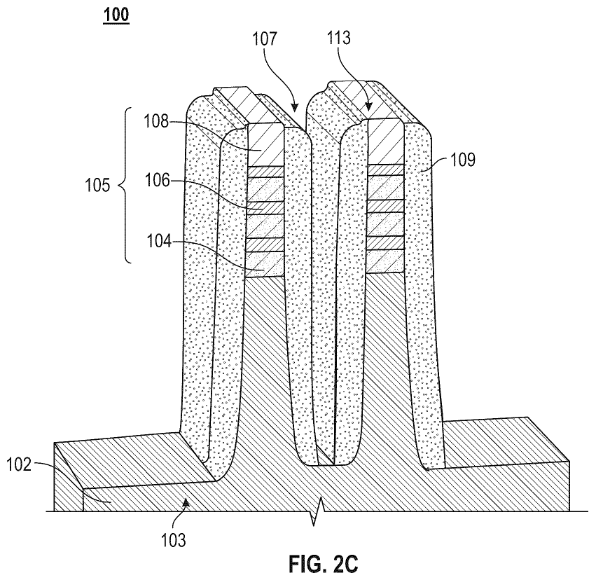

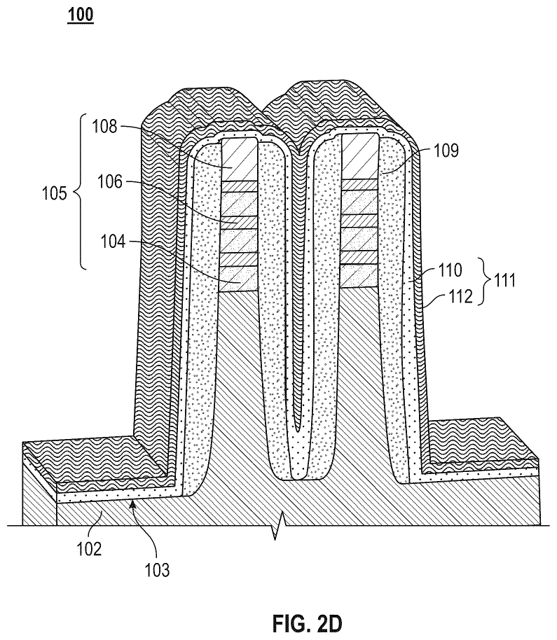

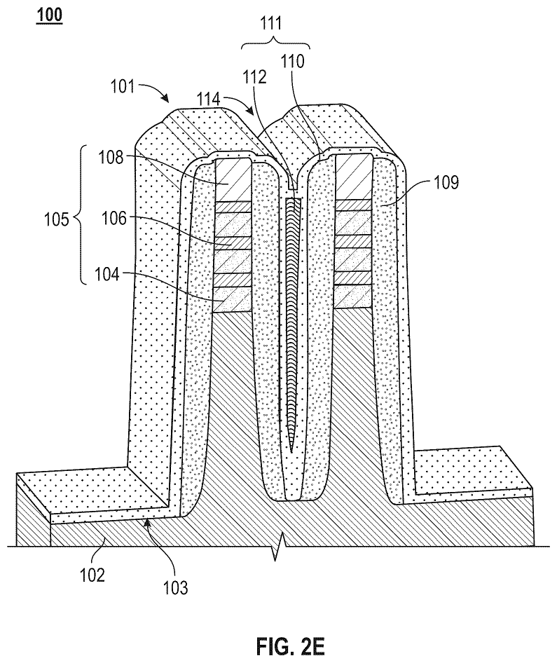

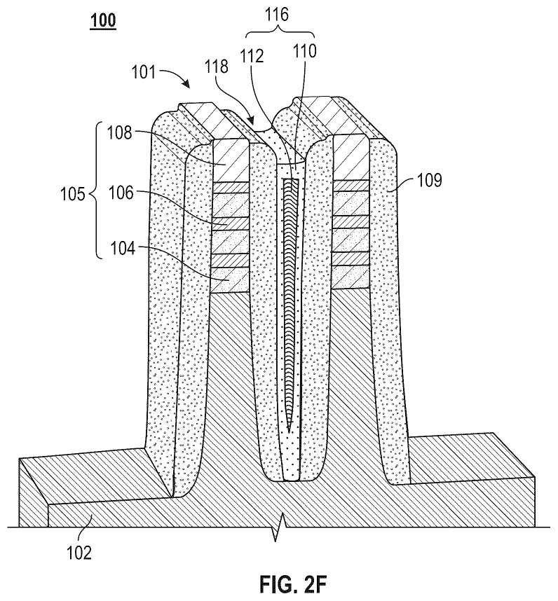

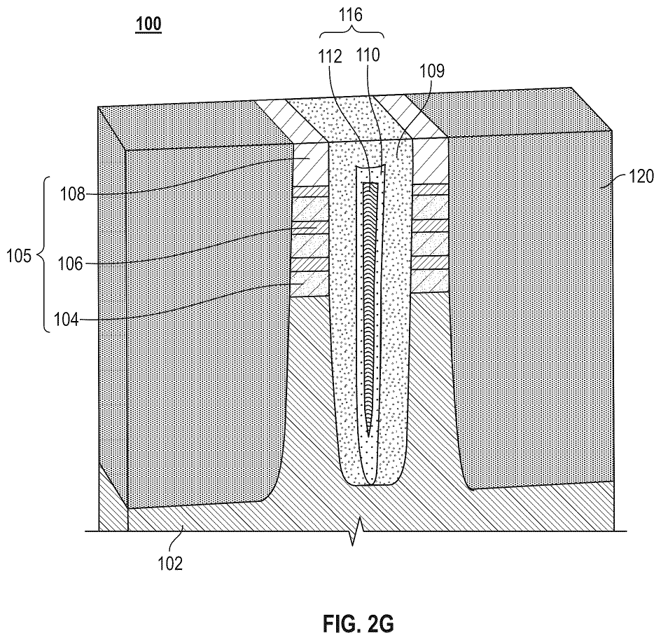

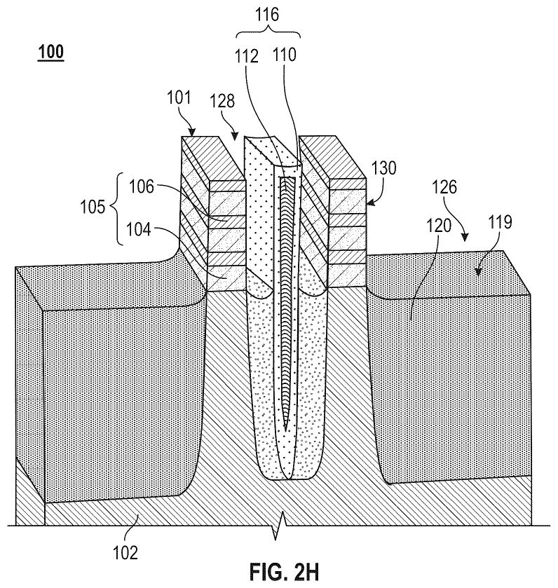

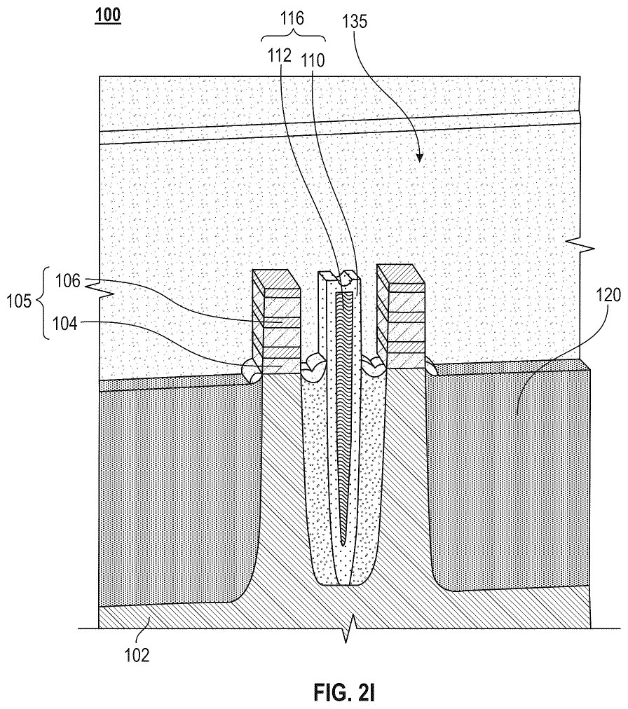

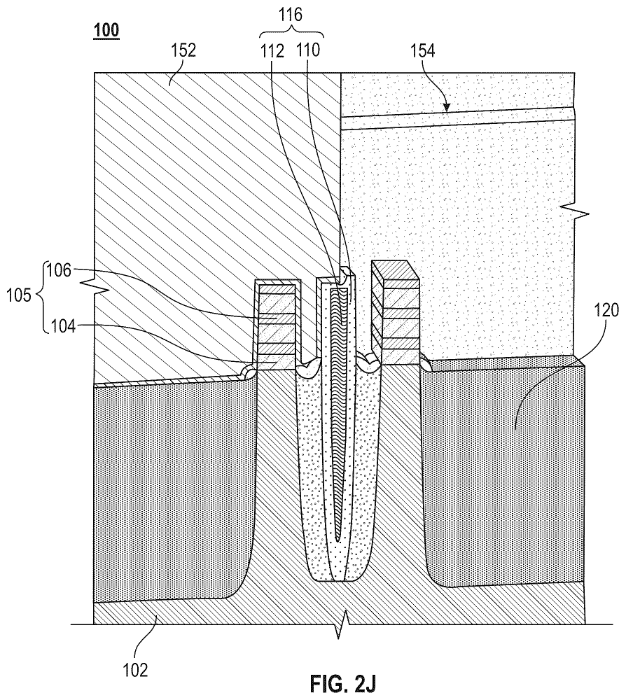

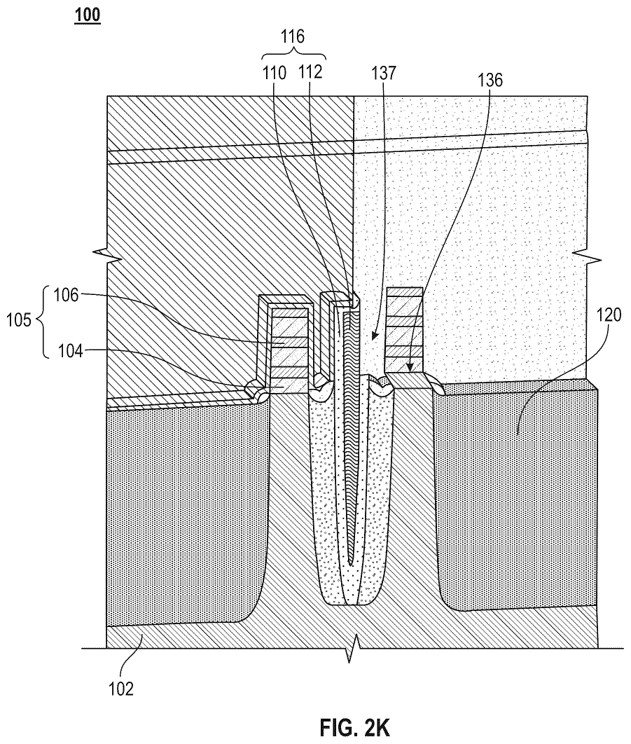

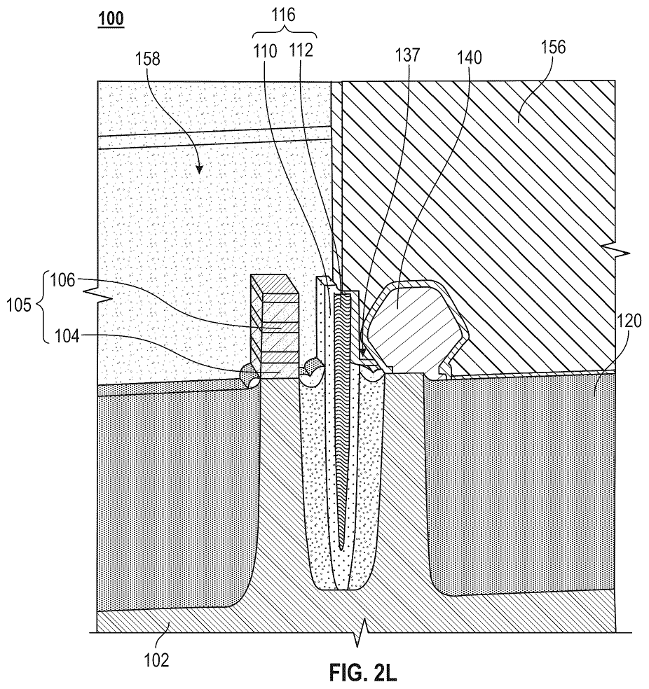

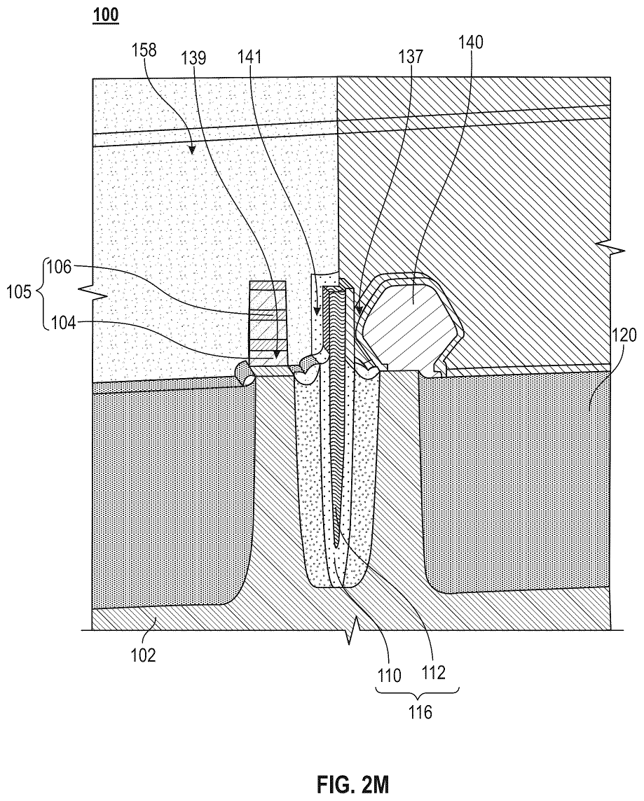

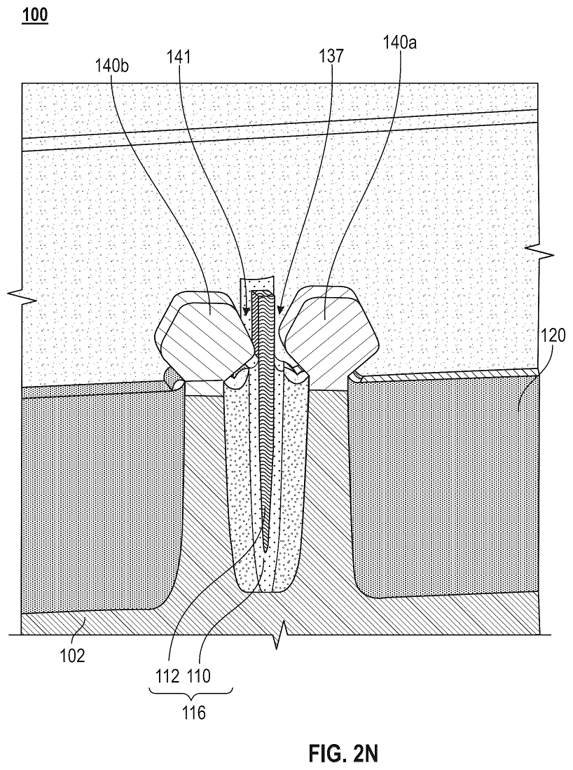

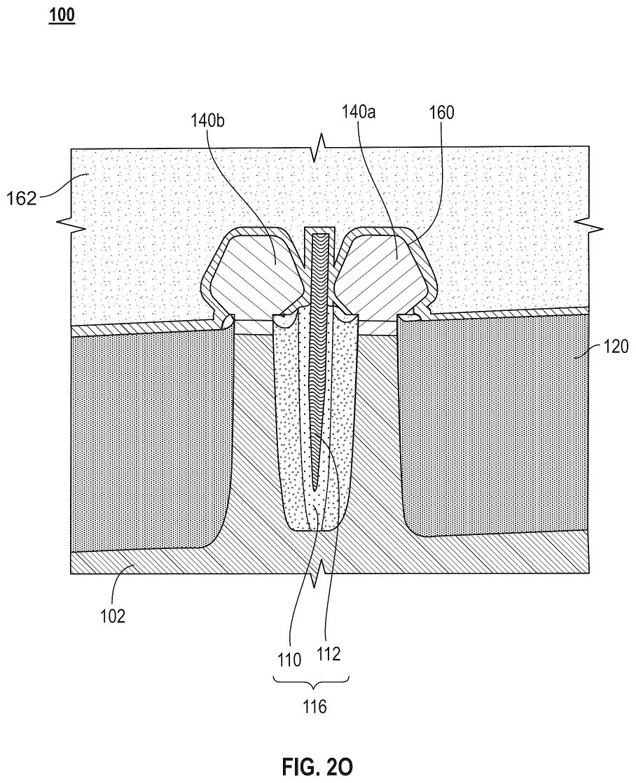

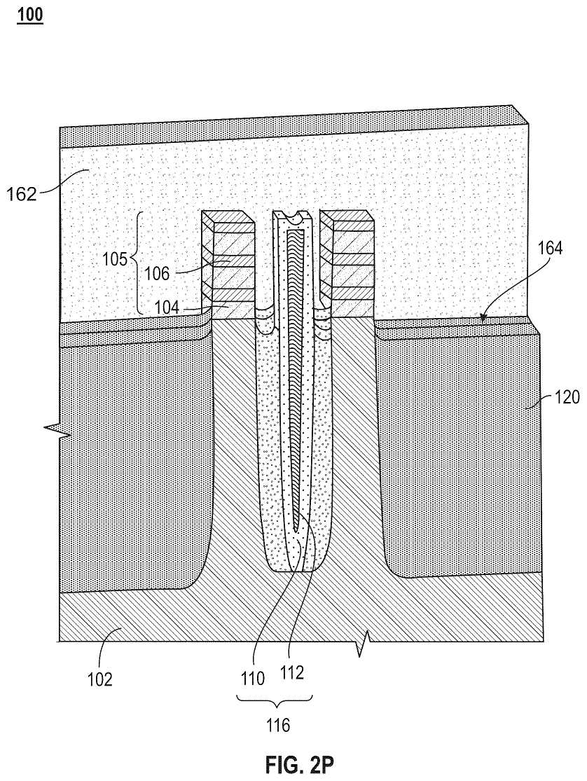

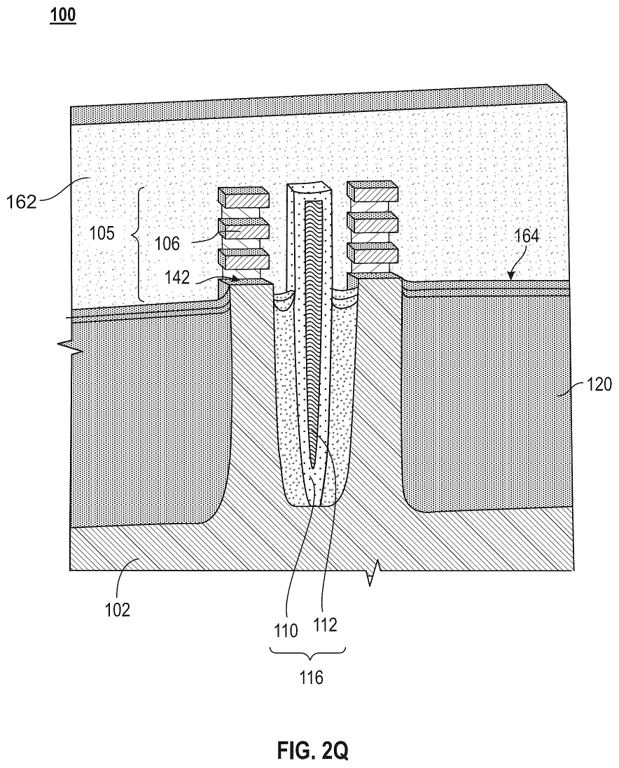

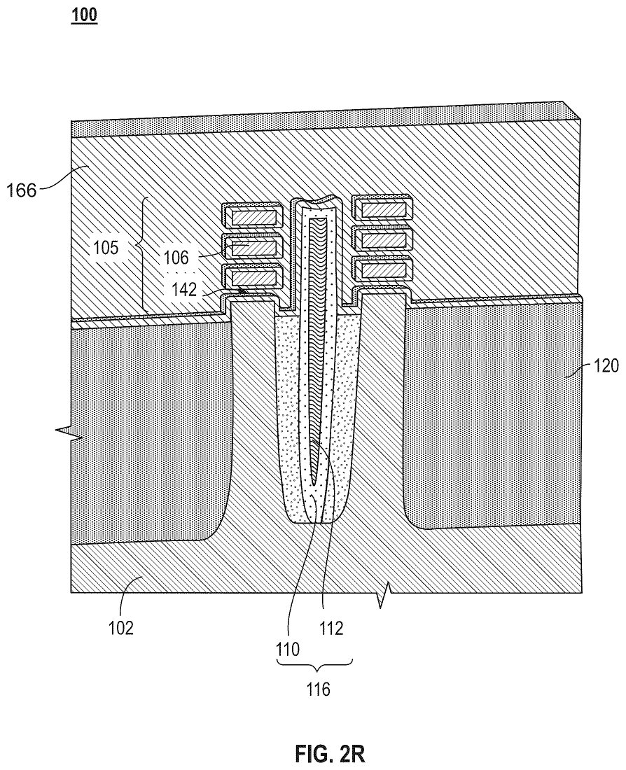

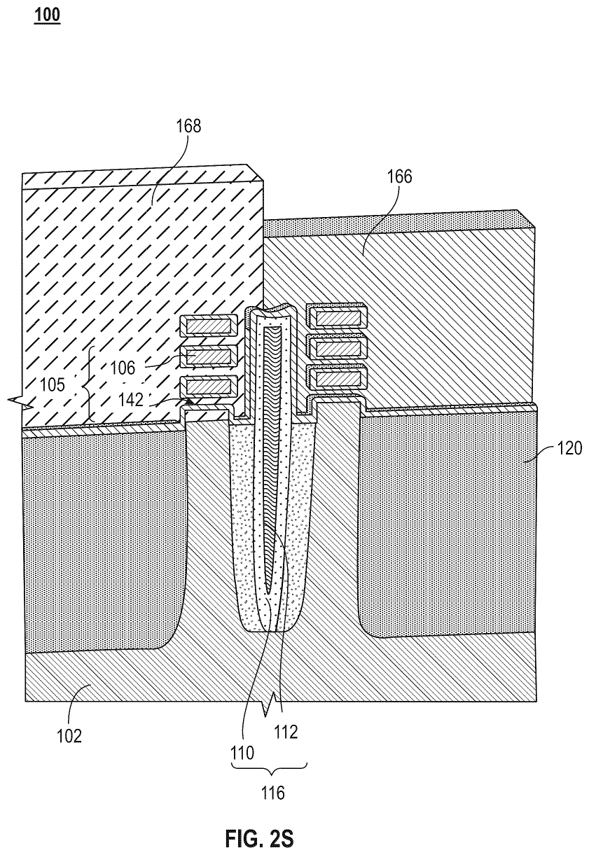

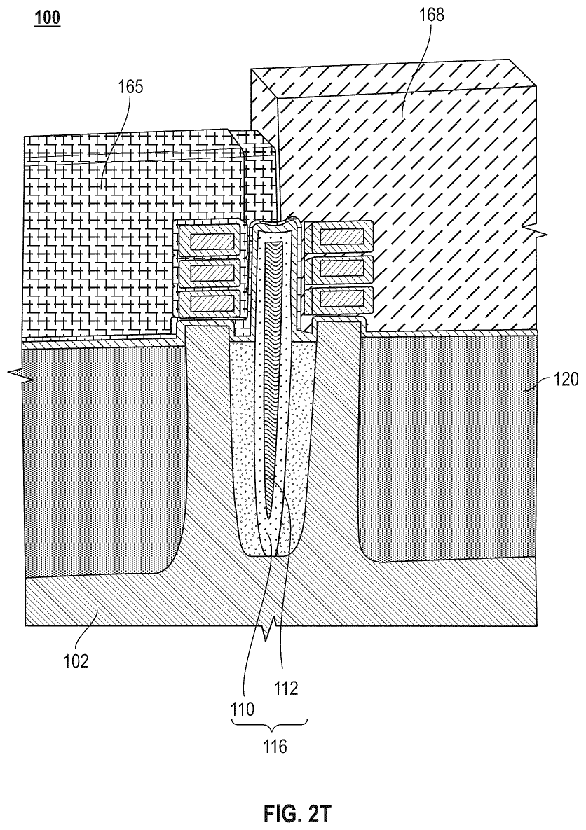

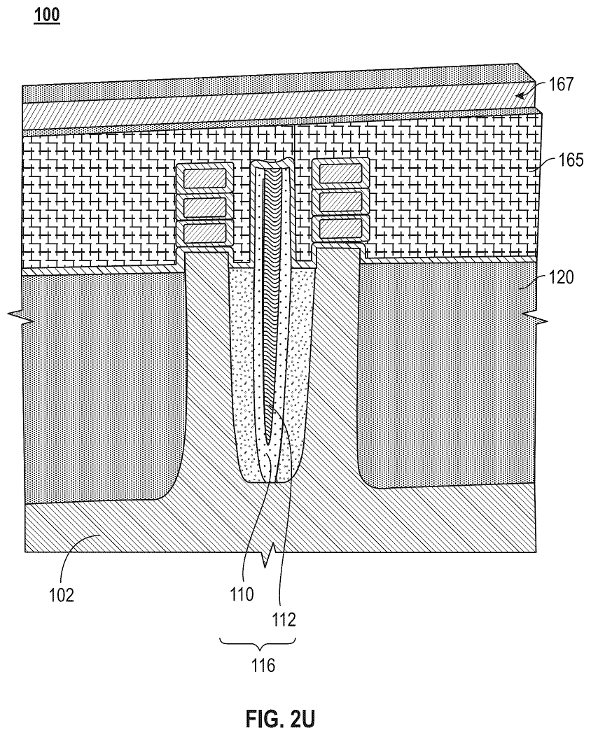

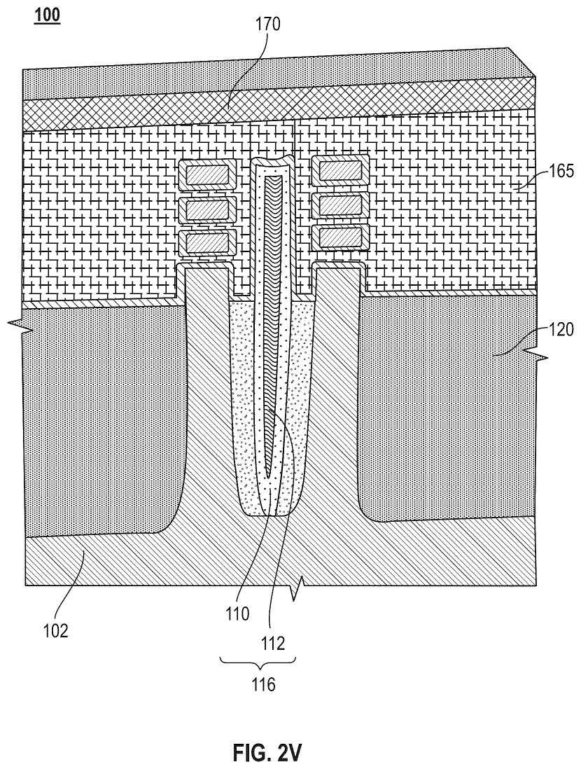

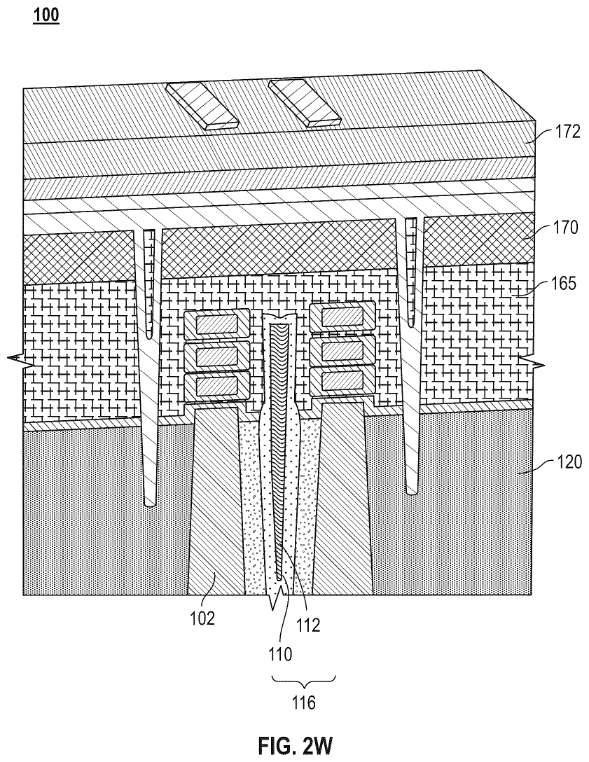

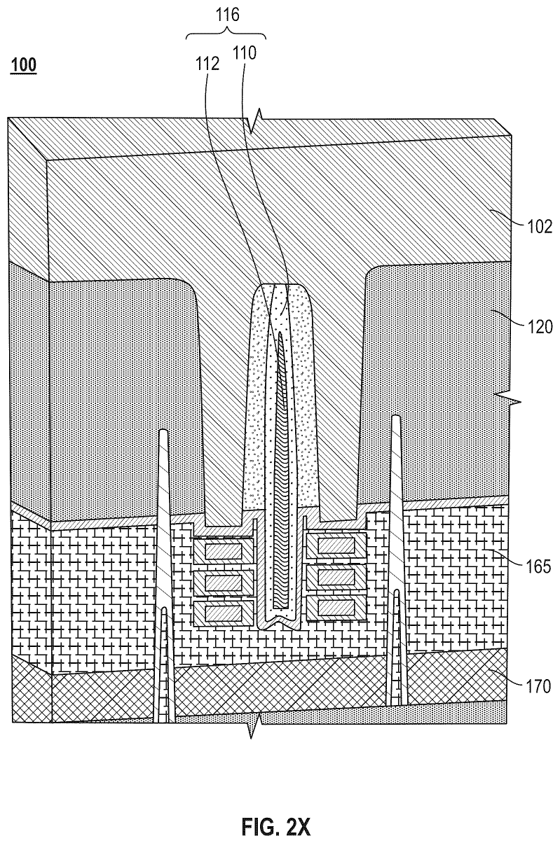

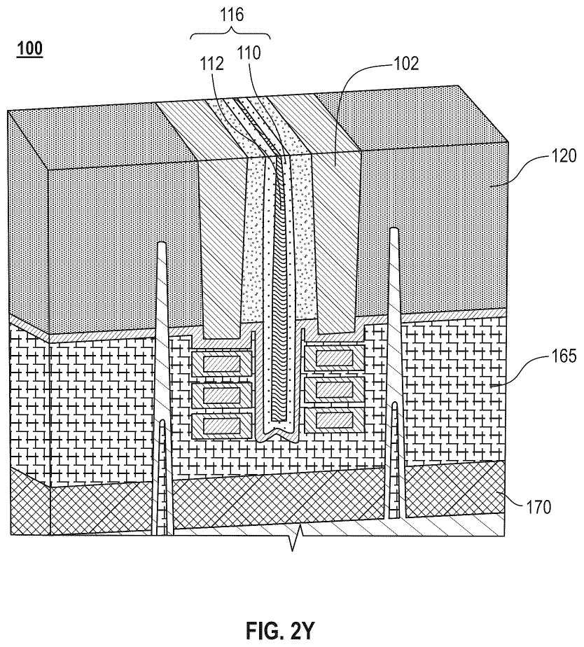

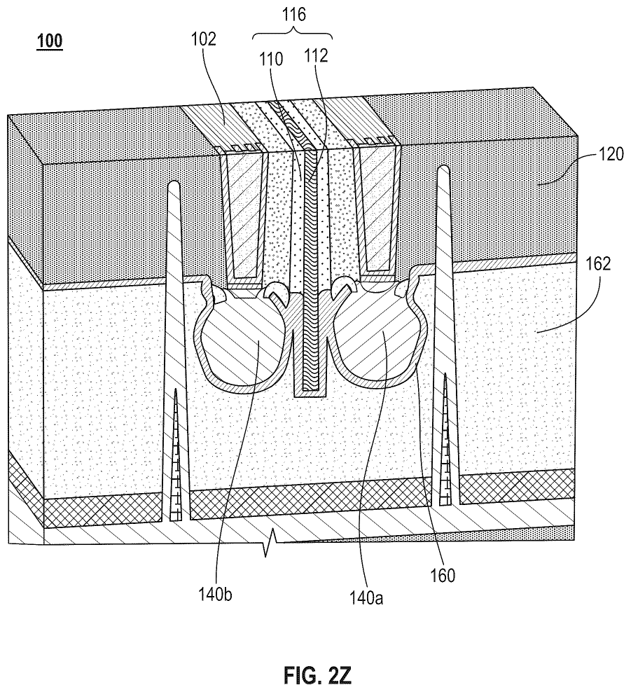

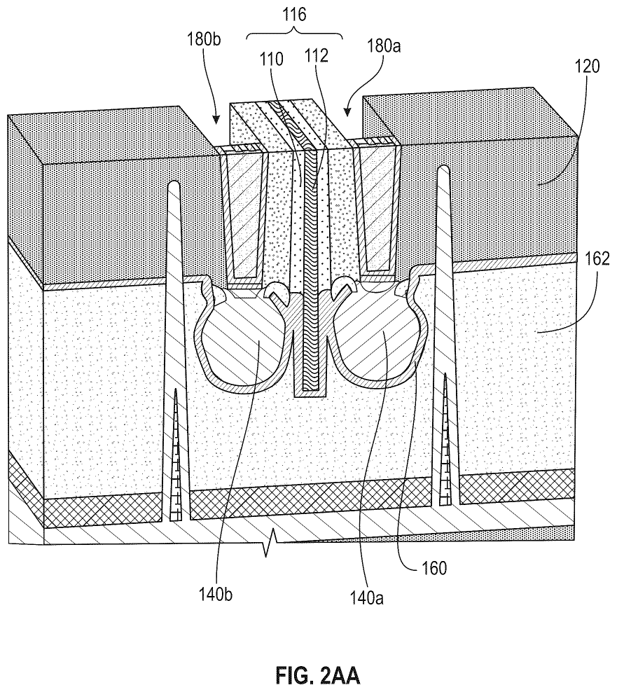

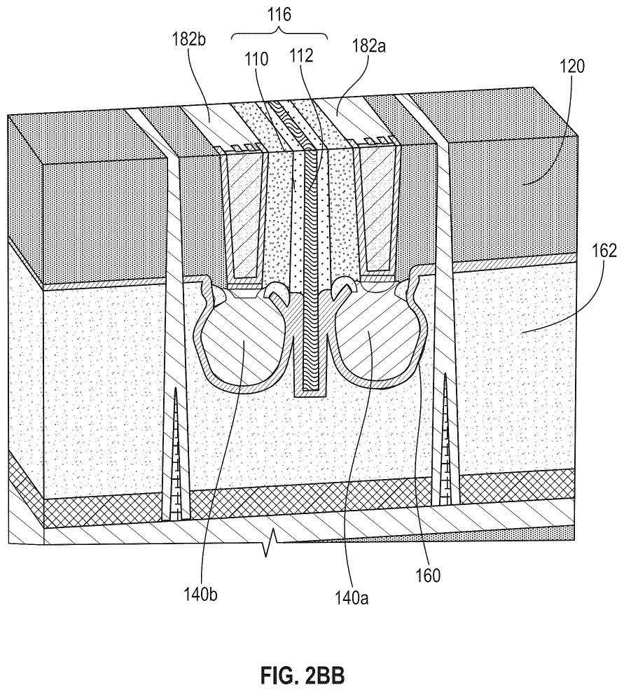

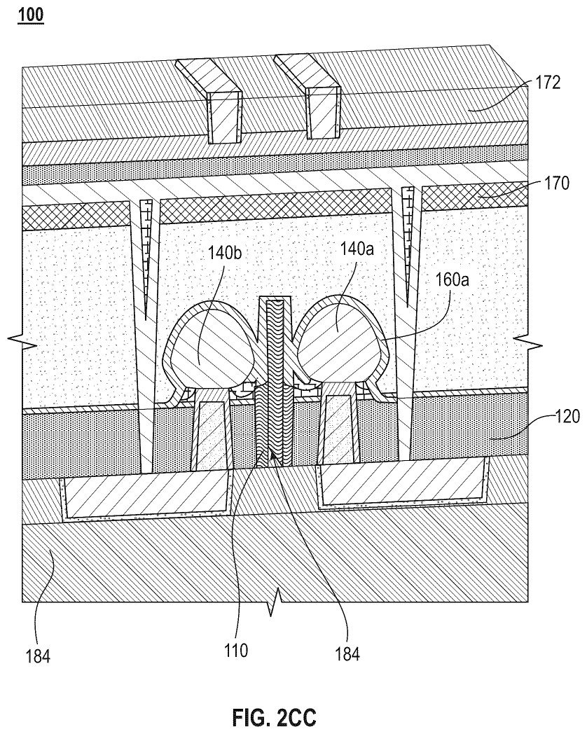

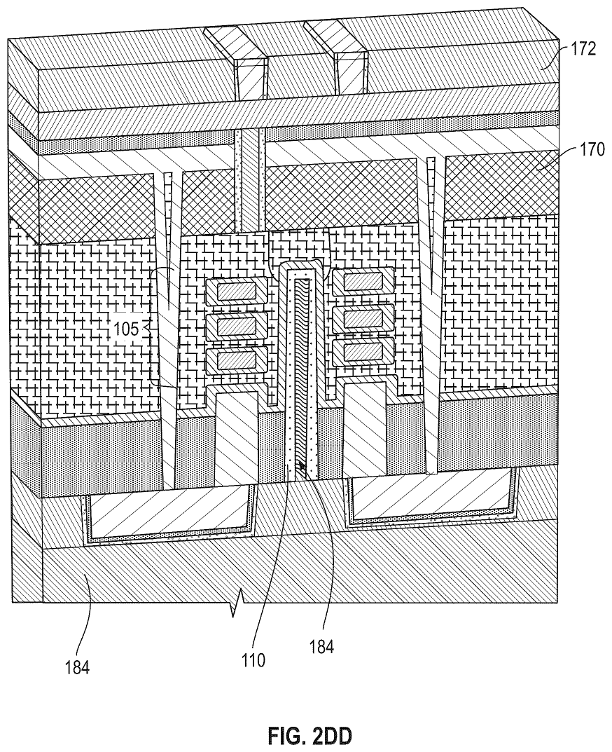

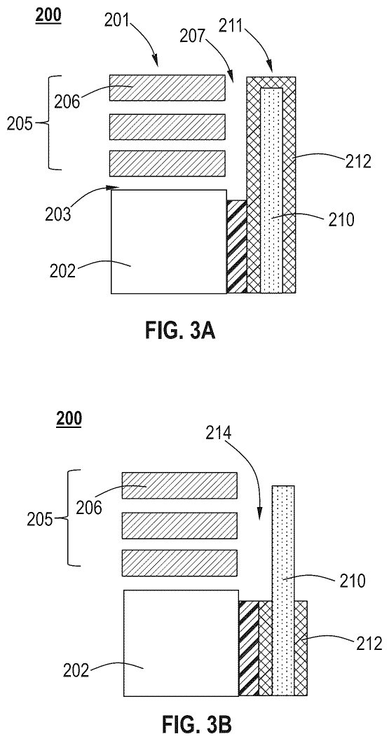

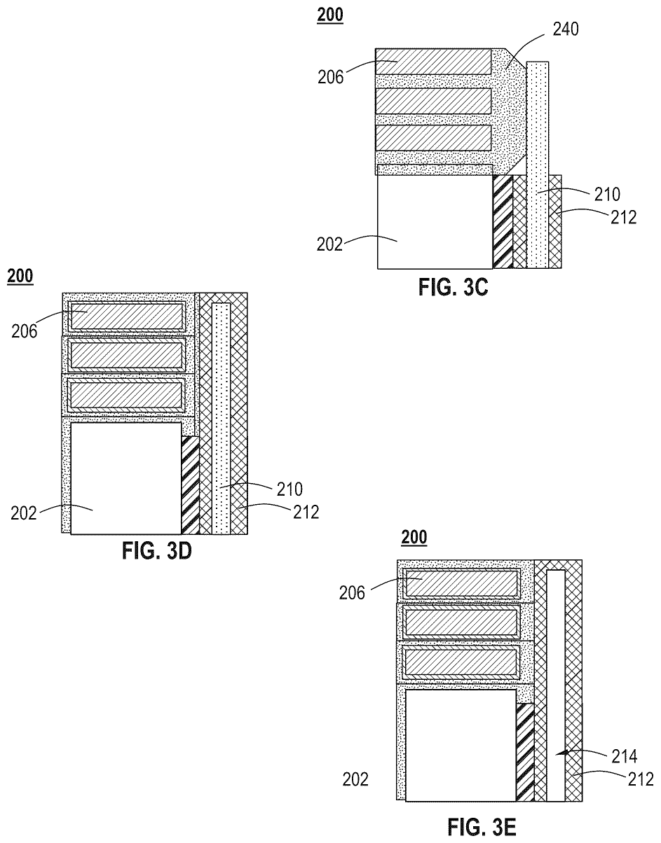

FIG. 1 illustrates a process flow diagram for a method 10 for forming a semiconductor device in accordance with some embodiments of the present disclosure. The method 10 is described below with respect to FIGS. 2A-2CC and FIGS. 3A-3E, which depict the stages of fabrication of semiconductor structures in accordance with one or more embodiments of the present disclosure. FIGS. 2A-2CC and FIGS. 3A-3E are cross-sectional views of an electronic device (e.g., a GAA) according to one or more embodiments. The method 10 may be part of a multi-step fabrication process of a semiconductor device. Accordingly, the method 10 may be performed in any suitable process chamber coupled to a cluster tool. The cluster tool may include process chambers for fabricating a semiconductor device, such as chambers configured for etching, deposition, epitaxial growth, physical vapor deposition (PVD), chemical vapor deposition (CVD), oxidation, or any other suitable chamber used for the fabrication of a semiconductor device. In one or more embodiments, the method may be performed in a processing chamber or cluster tool without breaking vacuum.

The method 10 begins at operation 12, by providing a substrate 102 (as illustrated in FIG. 2A). In some embodiments, the substrate 102 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the semiconductor substrate 102 comprises a semiconductor material, e.g., silicon (Si), carbon (C), germanium (Ge), silicon germanium (SiGe), germanium tin (GeSn), other semiconductor materials, or any combination thereof. In one or more embodiments, the substrate 102 comprises one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof. In some embodiments, the substrate 102 may be doped to provide a high dose of dopant at a first location of the surface of the substrate 102 in order to prevent parasitic bottom device turn on. For example, in some embodiments, the surface of the substrate may have a dopant density of about 10¹⁸ atoms/cm³ to about 10¹⁹ atoms/cm³.

In one or more embodiments, the device being formed are gate-all-around transistors, FinFET transistors, or CFET transistors, and a bilayer dielectric wall is formed in an opening between a first channel region for a first transistor and a second channel region for a second transistor. In some embodiments, the first transistor and the second transistor are on a substrate, the opening extending at least partially into the substrate, and the bilayer dielectric wall fills the opening.

In other embodiments, the device being formed is a FinFET, GAA, or a CFET. In one or more embodiments, at least one superlattice structure 105 (or channel region for a transistor) is formed atop the top surface 103 of the substrate 102 (as depicted in FIG. 2A). In some embodiments, the superlattice structure 105 may include a plurality of semiconductor material layers 106 and a corresponding plurality of release layers 104 alternatingly arranged in a plurality of stacked pairs. In some embodiments the plurality of stacked groups of layers comprises a silicon (Si) and silicon germanium (SiGe) group. In some embodiments, the plurality of semiconductor material layers 106 and corresponding plurality of release layers 104 can comprise any number of lattice matched material pairs suitable for forming a superlattice structure 105. In some embodiments, the plurality of semiconductor material layers 106 and corresponding plurality of release layers 104 comprise from about 2 to about 50 pairs of lattice matched materials.

Typically, a parasitic device will exist at the bottom of the superlattice structure 105. In some embodiments, implantation of a dopant in the substrate 102, as discussed above, is used to suppress the turn on of the parasitic device. In some embodiments, the substrate 102 is etched so that the bottom portion of the superlattice structure 105 includes a substrate portion which is not removed, allowing the substrate portion to act as the bottom release layer of the superlattice structure 105.

In one or more embodiments, the thicknesses of the semiconductor material layers 106 and release layers 104 in some embodiments are in the range of from about 2 nm to about 50 nm, in the range of from about 3 nm to about 20 nm, or in a range of from about 2 nm to about 15 nm. In some embodiments, the average thickness of the semiconductor material layers 106 is within 0.5 to 2 times the average thickness of the release layers 104.

With reference to FIG. 1 and FIG. 2A, in one or more embodiments, at operation 16, the superlattice structure 105 is patterned to form an opening 107 between adjacent stacks 101. The patterning may be done by any suitable means known to the skilled artisan. As used in this regard, the term “opening” means any intentional surface irregularity. Suitable examples of openings include, but are not limited to, trenches which have a top, two sidewalls and a bottom. Openings can have any suitable aspect ratio (ratio of the depth of the feature to the width of the feature). In some embodiments, the aspect ratio of the opening 107 is greater than or equal to about 5:1, about 10:1, about 15:1, about 20:1, about 25:1, about 30:1, about 35:1 or about 40:1.

Referring to FIG. 1 and FIG. 2B, in one or more embodiments, at operation 18, a shallow trench isolation (STI) liner 109 is deposited on the superlattice structure 105 and on the top surface 103 of the substrate. As used herein, the term “shallow trench isolation (STI)” refers to an integrated circuit feature which prevents current leakage. In one or more embodiments, the shallow trench isolation (STI) liner 109 may comprise any suitable material known to the skilled artisan. In one or more embodiments, the shallow trench isolation (STI) liner 109 comprises silicon oxide (SiOx).

Referring to FIG. 2C, in one or more embodiments, the shallow trench isolation (STI) liner 109 is subjected to direction reactive ion etching to thin the shallow trench isolation (STI) liner 109 and expose the top surface 103 of the substrate 102 and to expose the top surface 113 of the nanosheet hard mask 108.

With reference to FIG. 1 and FIG. 2D, at operation 20, a bilayer dielectric wall 111 is formed on the superlattice structures 105 of each stack 101. In one or more embodiments, the bilayer dielectric wall 111 includes a first or liner dielectric layer 110 and a second or core dielectric layer 112. Referring to FIG. 2D, in one or more embodiments, the liner dielectric layer 110 is deposited on the surface of the shallow trench isolation (STI) liner 109, on the top surface 103 of the substrate 102. In one or more embodiments, the core dielectric layer 112 is then deposited on the liner dielectric layer 110.

In one or more embodiments, the core dielectric layer 112 may comprise any suitable dielectric material. In one or more embodiments, the core dielectric layer 112 comprises a high-κ dielectric material. As used herein, the term “high-κ dielectric material” refers to a material with a dielectric constant greater than the dielectric constant of silicon dioxide. Without intending to be bound by theory, it is thought that the core dielectric layer 112 advantageously provides protection for downstream dry and wet etching. The high-k dielectric material can be any suitable high-k dielectric material deposited by any suitable deposition technique known to the skilled artisan. In at least some embodiments, the core dielectric layer 112 may be selected from one or more of hafnium oxide (HfOx), hafnium nitride (HfN), aluminum oxide (AlOx), aluminum nitride (AlN), and the like.

In one or more embodiments, the thickness of the core dielectric layer 112 is in an approximate range from about 5 nanometers (nm) to about 20 nanometers (nm), including in a range of from about 7 nm to about 5 nm. In one or more embodiments, the core dielectric layer 112 may be deposited using any suitable technique. In some embodiments, the core dielectric layer 112 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

In one or more embodiments, the liner dielectric layer 110 may comprise any suitable dielectric material. In some embodiments, the liner dielectric layer 110 includes a low-k dielectric material. In some embodiments, the low-K dielectric material has a k-value less than 7 or less than 5 or less than 2. In at least some embodiments, liner dielectric layer 110 includes oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof. In at least some embodiments, liner dielectric layer 110 may be selected from one or more of silicon carbonitride (SiCN), silicon oxynitride (SiON), silicon oxycarbonitride (SiOCN), silicon oxycarbide (SiOC), and the like.

In one or more embodiments, the thickness of the liner dielectric layer 110 is in an approximate range from about 1 nanometers (nm) to about 15 nanometers (nm), including in a range of from about 3 nm to about 11 nm. In one or more embodiments, the liner dielectric layer 110 may be deposited using any suitable technique. In some embodiments, the liner dielectric layer 110 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

Referring to FIG. 1 and FIG. 2E, in one or more embodiments, at operation 22, the core dielectric layer 112 is recessed to expose the liner dielectric layer 110 and form a recessed region 114 between the adjacent stacks 101 of superlattice structures 105. In one or more embodiments, a portion of the core dielectric layer 112 remains in the opening 107 between the stacks. The core dielectric layer 112 may be removed by any suitable means known to the skilled artisan. In one or more embodiments, the core dielectric layer 112 is removed by isotropic etching.

With reference to FIG. 1 and FIG. 2E, in one or more embodiments, at operation 24, an additional layer of the liner dielectric layer 110 is formed on the adjacent stacks 101 and in the recessed region 114 between the adjacent stacks. In one or more embodiments, the liner dielectric layer 110 encapsulates the core dielectric layer 112 between the stacks 101 to form an encapsulated bilayer dielectric wall 116. As used herein, the term “encapsulate” refers to the core dielectric layer 112 being enclosed or surrounded completely by the liner dielectric layer 110 in the region located between adjacent stacks 101.

With reference to FIG. 1 and FIG. 2F, in one or more embodiments, at operation 26, the liner dielectric layer 110 is removed to expose the stacks 101 of the superlattice structures 105. The liner dielectric layer 110 may be removed by any suitable means known to the skilled artisan. In one or more embodiments, the liner dielectric layer 110 is removed by isotropic etching. It is noted that the encapsulated bilayer dielectric wall 116 between the adjacent stacks 101 remains after etching. A recess region 118 is formed between the adjacent stacks 101.

Referring to FIG. 1 and FIG. 2G, in one or more embodiments, at operation 28, a shallow trench isolation (STI) 120 is formed. As used herein, the term “shallow trench isolation (STI)” refers to an integrated circuit feature which prevents current leakage. In one or more embodiments, STI is created by depositing one or more dielectric materials (such as silicon dioxide) to fill the recess region 118 and surround the adjacent stacks 101. In one or more embodiments, the shallow trench isolation (STI) 120 may comprise any suitable material known to the skilled artisan. In one or more embodiments, the shallow trench isolation (STI) 120 comprises silicon oxide (SiOx).

Referring to FIG. 1 and FIG. 2G, at operation 30, in one or more embodiments, the excess overburden of shallow trench isolation (STI) 120 may be removed using a technique such as chemical-mechanical planarization (CMP), exposing a top surface 119 of the shallow trench isolation (STI) 120.

With reference to FIG. 1 and FIG. 2H, at operation 32, in one or more embodiments, the nanosheet hard mask 108 and the STI liner 109 are recessed to form an opening 126 in the shallow trench isolation (STI) 120 and an opening 128 between the superlattice structures 105 of each stack 101.

In one or more embodiments, at operation 34, as illustrated in FIG. 1 and FIG. 2H, the sidewall surface 130 of the nanosheets of the superlattice structures 105 is revealed by removal of a portion of the shallow trench isolation (STI) 120 adjacent to the superlattice structures 105. The nanosheet reveal of operation 34 may occur by any suitable process known to the skilled artisan. In one or more embodiments, the shallow trench isolation (STI) 120 is removed by wet etch or dry etch. In one or more embodiments, the etching uses a wet etch process, such as diluted hydrofluoric acid (DHF). In one or more embodiments, a dry etch process is used. In some embodiments, the dry etch process may include a conventional plasma etch, or a remote plasma-assisted dry etch process, In the etch process of one or more embodiments, the device is exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The etch process of one or more embodiments may be performed in any suitable chamber, which may be integrated into one of a variety of multi-processing platforms. In one or more embodiments, a wet etch process may be used which includes a hydrofluoric (HF) acid last process, in which HF etching of surface is performed that leaves surface hydrogen-terminated. Alternatively, any other liquid-based etch process may be employed. In some embodiments, the process comprises a sublimation etch. The etch process can be plasma or thermally based. The plasma processes can be any suitable plasma (e.g., conductively coupled plasma, inductively coupled plasma, microwave plasma). For example, in one or more embodiments, the shallow trench isolation (STI) 120 may be exposed to H₂, NF₃, and/or NH₃ plasma species, e.g., plasma-excited hydrogen and fluorine species. The etch process may be plasma or thermally based. The plasma etch process can use any suitable plasma (for example, conductively coupled plasma, inductively coupled plasma, or microwave plasma) known to the skilled artisan.

With reference to FIG. 1 and FIG. 2I, at operation 36, in some embodiments, a dummy gate structure 135 is formed over and adjacent to the superlattice structure 105. The dummy gate structure 135 defines the channel region of the transistor device. The dummy gate structure 135 may be formed using any suitable conventional deposition and patterning process known in the art.

In one or more embodiments, the dummy gate structure 135 comprises one or more of a sacrificial oxide layer, a dummy poly-silicon gate, and a spacer layer.

With reference to FIG. 1 and FIG. 2J, at operation 38, a hardmask 152 is deposited over the adjacent stacks 101 of superlattice structures 105. In one or more embodiments, a first side 154, or the PMOS side in some embodiments, is patterned and the hardmask 152 is etched.

Referring to FIG. 1 and FIG. 2K, in some embodiments, at operation 40, a source/drain trench 136 is formed adjacent the superlattice structure 105 and the bilayer dielectric wall 116 is recessed such that a portion of the liner dielectric layer 110 is removed to form an opening 137 adjacent to the superlattice structure 105. Without intending to be bound by theory, it is thought that removal of the liner dielectric layer 110 adjacent to the source/drain trench 136 advantageously allows more space for the epitaxial source/drain for improved device performance.

The source/drain trenches 136 may be formed by any suitable means known to the skilled artisan. In one or more embodiments, the source/drain trenches 136 (or a plurality of source trenches and a plurality of drain trenches adjacent to the first superlattice structure and the second superlattice structure) are formed by etching. The etch process of operation 40 may include any suitable etch process that is selective to the source/drain trenches 136. In some embodiments the etch process of operation 40 comprises one or more of a wet etch process or a dry etch process. The etch process may be a directional etch.

In some embodiments, the dry etch process may include a conventional plasma etch, or a remote plasma-assisted dry etch process. In the etch process of one or more embodiments, the device may be exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The etch process may be performed in a preclean chamber, which may be integrated into one of a variety of multi-processing platforms. The wet etch process may include a hydrofluoric (HF) acid last process, i.e., the so-called “HF last” process, in which HF etching of surface is performed that leaves surface hydrogen-terminated. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

With reference to FIG. 2L and to FIG. 1, at operation 42, in some embodiments, an embedded source/drain region 140 is formed in the source/drain trench 136. In some embodiments, the source region 140 is formed adjacent a first end of the superlattice structure 105. In other embodiments, the drain region 140 is formed adjacent the superlattice structure 105. In some embodiments, the source region and/or drain region 140 are formed from any suitable semiconductor material, such as but not limited to silicon (Si), germanium (Ge), silicon germanium (SiGe), silicon phosphorous (SiP), silicon arsenic (SiAs), or the like. In some embodiments, the source/drain regions 140 may be formed using any suitable deposition process, such as an epitaxial deposition process. In some embodiments, the source/drain regions 140 are independently doped with one or more of phosphorus (P), arsenic (As), boron (B), and gallium (Ga). In one or more embodiments, a hardmask 156 is deposited over the adjacent stacks 101 of superlattice structures 105. In one or more embodiments, a second side 158, or the NMOS side, in some embodiments, is patterned and the hardmask 156 is etched.

Referring to FIG. 1 and FIG. 2M, at operation 44, in one or more embodiments, the hardmask 156 is removed and a source/drain trench 138 is formed adjacent the superlattice structure 105 and on the opposing side of the source/drain trench 136. In one or more embodiments, the bilayer dielectric wall 116 is recessed such that a portion of the liner dielectric layer 110 is removed to form an opening 141 adjacent to the superlattice structure 105 and on an opposing side, second side 158, of opening 137. Without intending to be bound by theory, it is thought that removal of the liner dielectric layer 110 adjacent to the source/drain trench 138 advantageously allows more space for the epitaxial source/drain for improved device performance.

The source/drain trench 138 may be formed by any suitable means, as described above with respect to source/drain trench 136.

With reference to FIG. 2N and to FIG. 1, at operation 44, in some embodiments, an embedded source/drain region 140b is formed in the source/drain trench 138. In some embodiments, the source region 140b is formed adjacent a second end of the superlattice structure 105 on an opposing side of the drain region 140a. In other embodiments, the drain region 140b is formed adjacent the superlattice structure 105 on the opposing side of the source region 140a. In some embodiments, the source region and/or drain region 140a, 140b are formed from any suitable semiconductor material, such as but not limited to silicon (Si), germanium (Ge), silicon germanium (SiGe), silicon phosphorous (SiP), silicon arsenic (SiAs), or the like. In some embodiments, the source/drain regions 140a, 140b may be formed using any suitable deposition process, such as an epitaxial deposition process. In some embodiments, the source/drain regions 140a, 140b are independently doped with one or more of phosphorus (P), arsenic (As), boron (B), and gallium (Ga).

Referring to FIG. 2O and to FIG. 1, at operation 46, in one or more embodiments, a CESL liner 160 is formed on the embedded source/drain regions 140a, 140b and on the bilayer dielectric wall 116. In one or more embodiments, a MOL oxide fill 162 is deposited. In one or more embodiments, the CESL liner 160 is formed with an insulating material, such as silicon nitride (SiN), that can be etched selectively to the MOL dielectric 162 and, as such, provides an etch stop for the subsequent contact patterning into the MOL dielectric material. The CESL liner 160 is also a barrier that prevents diffusion of contaminants that can degrade the device electrical characteristics. The MOL dielectric fill 162 can be formed from oxide or any suitable low K material to mitigate device parasitics. In addition, the MOL dielectric fill material 162 must provide etch selectivity to the subsequent RMG poly-silicon and sacrificial oxide removal processes. The MOL dielectric fill 162 can be recessed, post MOL dielectric CMP, and back filled with a denser dielectric material to provide the etch selectivity for the RMG removal processes.

With reference to FIG. 2P and to FIG. 1, at operation 48, in one or more embodiments, poly-open CMP, poly removal, sacrificial oxide removal. In one or more embodiments, the liner dielectric layer 110 is maintained in the gate to protect the high-κ layer when the core dielectric layer 112 is removed later in the process. Without the protection from the liner dielectric layer 110, the high-κ material is directly exposed to ingress of contaminants that would degrade the device. Without intending to be bound by theory, it is known that the electronic states at the interface of the high-κ establish the band alignment to the adjacent materials and, therefore, the device threshold voltage. Oxygen and/or metallic contaminants accumulating at these interfaces will shift the threshold of the device from the target and degrade the device performance.

Referring to FIG. 1 and FIGS. 2Q thru 2T, at operations 50 and 52, the formation of the semiconductor device, e.g., GAA, continues according to traditional procedures with nanosheet release and replacement metal gate 165 formation. Specifically, in one or more unillustrated embodiments, the plurality of semiconductor material layers 104 are selectively etched between the plurality of horizontal channel layers 106 in the superlattice structure 105. For example, where the superlattice structure 105 is composed of silicon (Si) layers and silicon germanium (SiGe) layers, the silicon germanium (SiGe) is selectively etched to form channel nanowires. The plurality of semiconductor material layers 104, for example silicon germanium (SiGe), may be removed using any well-known etchant that is selective to the plurality of horizontal channel layers 106 where the etchant etches the plurality of semiconductor material layers 104 at a significantly higher rate than the plurality of horizontal channel layers 106. In some embodiments, a selective dry etch or wet etch process may be used. In some embodiments, where the plurality of horizontal channel layers 106 are silicon (Si) and the plurality of semiconductor material layers 104 are silicon germanium (SiGe), the layers of silicon germanium may be selectively removed using a wet etchant such as, but not limited to aqueous carboxylic acid/nitric acid/HF solution and aqueous citric acid/nitric acid/HF solution. The removal of the plurality of semiconductor material layers 104 leaves voids 142 between the plurality of horizontal channel layers 106. The voids 142 between the plurality of horizontal channel layers 106 have a thickness of about 3 nm to about 20 nm. The remaining horizontal channel layers 106 form a vertical array of channel nanowires that are coupled to the source/drain regions 140. The channel nanowires run parallel to the top surface of the substrate 102 and are aligned with each other to form a single column of channel nanowires.

In one or more embodiments, as illustrated in FIG. 2R, an interlayer oxide is selectively deposited on the channel silicon nanowires over which a high-k dielectric 166 is formed. The high-k dielectric 166 can be any suitable high-k dielectric material deposited by any suitable deposition technique known to the skilled artisan. The high-k dielectric 166 of some embodiments comprises hafnium oxide. In some embodiments, a conductive material such as titanium nitride (TiN), tungsten (W), cobalt (Co), aluminum (Al), or the like is deposited on the high-k dielectric 166 to form the replacement metal gate. The conductive material may be formed using any suitable deposition process such as, but not limited to, atomic layer deposition (ALD) in order to ensure the formation of a layer having a uniform thickness around each of the plurality of channel layers.

Referring to FIG. 1 and FIGS. 2S and 2T, at operation 52, the work function metal (WFM) is patterned on both the PMOS and NMOS side of the device 100, and the replacement metal gate 165 is formed. The WFM patterning is made separately for the PMOS and NMOS and can be made multiple times for each threshold voltage device in the technology design.

With reference to FIG. 1 and FIGS. 2U and 2V, at operation 54, the replacement metal gate 166 is planarized by any suitable means. In some embodiments, the replacement metal gate 166 is planarized by chemical mechanical planarization (CMP) to leave a recess opening 167. In one or more embodiments, a gate cap 170 is formed in the recess opening 167. With reference to FIG. 1 and FIG. 2W, the metal line (M0) 172 is formed and electrically connected to the via (V0). In one or more embodiments, after the replacement metal gate 166 is formed, a contact to transistor and a contact to gate are formed in electrical contact with the source region and the drain region.

With reference to FIG. 2X, the device 100 is flipped and channel release occurs, where the sacrificial silicon germanium (SiGe) epitaxial layers are removed to expose all sides of the silicon nano-slab. As illustrated in FIG. 2Y, the interfacial layer is grown and a layer of high-k material is conformally deposited. The substrate 102 is removed by chemical-mechanical planarization.

Referring to FIG. 2Z and FIG. 2AA, the device 100 is flipped to process the backside. The silicon portion of the nanosheet mesa is removed to form an opening 180a, 180b on both the PMOS and NMOS side of the device 100 to provide space for dielectric to isolate the source and drain of each device to mitigate leakage current.

With reference to FIG. 2BB, the opening 180a, 180b on both the PMOS and NMOS side of the device 100 is filled with dielectric material 182a, 182b. Following dielectric deposition, the device is chemical mechanical planarized to the final thickness 2BB.

Referring to FIG. 1 and FIG. 2CC, at operation 56, in one or more embodiments, the core dielectric layer 112 is removed during the wafer backside processing to form an airgap 184. The core dielectric material is selected such that in can be etched selectively to adjacent materials using reactive ion etch and/or wet etch methods. Without intending to be bound by theory, it is thought that the formation of the airgap 184, reduces the dielectric constant of material adjacent to the device and results in performance improvement due to the parasitic reduction. It is also thought that removal of the core dielectric layer 112 and formation of the airgap 184 also enables proper material selection for a robust process that will withstand the process sequence and enable the intended function of the dielectric wall. FIG. 2DD illustrates a cross-section of the device 100, parallel to, and at the same step in the process as FIG. 2CC, but the cross-section is taken through the gate. As illustrated, FIG. 2DD shows the encapsulated recessed portion of the core dielectric layer removed to form an airgap 184 between the channel regions of the superlattice structure 105.

Referring to FIG. 1 and FIGS. 3A-3E, which are cross-sectional views of a gate-all-around device according to one or more embodiments, the method 10 begins at operation 12, by providing a substrate 202 (as illustrated in FIG. 3A). In some embodiments, the substrate 202 may be a bulk semiconductor substrate as described above.

At least one superlattice structure 205 is formed atop the top surface 203 of the substrate 202 (as depicted in FIG. 3A). The superlattice structure 205 comprises a plurality of semiconductor material layers 206 and a corresponding plurality of release layers 204 or a corresponding plurality of voids alternatingly arranged in a plurality of stacked pairs. In some embodiments the plurality of stacked groups of layers comprises a silicon (Si) and silicon germanium (SiGe) group. In some embodiments, the plurality of semiconductor material layers 206 and corresponding plurality of release layers 204 can comprise any number of lattice matched material pairs suitable for forming a superlattice structure 205. In some embodiments, the plurality of semiconductor material layers 206 and corresponding plurality of release layers 204 comprise from about 2 to about 50 pairs of lattice matched materials.

With reference to FIG. 1 and FIG. 3A, in one or more embodiments, at operation 16, the superlattice structure 205 is patterned to form an opening 207. The patterning may be done by any suitable means known to the skilled artisan.

Referring to FIG. 1 and FIG. 3B, in one or more embodiments, at operation 18, a bilayer dielectric wall 211 is formed on the superlattice structures 205 and in the opening 207 between each stack 201. In one or more embodiments, the bilayer dielectric wall 211 includes a first or core or inner dielectric layer 210 and an outer or liner dielectric layer 212 that surrounds the first dielectric layer 210.

In one or more embodiments, the core or inner dielectric layer 210 may comprise any suitable dielectric material. In one or more embodiments, the inner or core dielectric layer 210 includes a high-k dielectric material. In at least some embodiments, the high-k dielectric material can be any suitable high-k dielectric material deposited by any suitable deposition technique known to the skilled artisan. In at least some embodiments, the inner or core dielectric layer 210 may be selected from one or more of hafnium oxide (HfOx), hafnium nitride (HfN), aluminum oxide (AlOx), aluminum nitride (AlN), and the like.

In one or more embodiments, the thickness of the core or inner dielectric layer 210 is in an approximate range from about 5 nanometers (nm) to about 20 nanometers (nm), including in a range of from about 7 nm to about 5 nm. In one or more embodiments, the core or inner dielectric layer 210 may be deposited using any suitable technique. In some embodiments, the first dielectric layer 210 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

In some embodiments, the second or outer dielectric layer 212 comprises a low-κ dielectric material. The second or outer dielectric layer 212 is provided as a spacer, in the formation of the dielectric wall, which is removed to advantageously provide space for the epitaxial layer 240, as illustrated in FIG. 3C. In at least some embodiments, the second or outer dielectric layer 212 may be selected from one or more of silicon carbonitride (SiCN), silicon oxynitride (SiON), silicon oxycarbonitride (SiOCN), silicon oxycarbide (SiOC), and the like.

In one or more embodiments, the thickness of the second or outer dielectric layer 212 is in an approximate range from about 1 nanometer (nm) to about 15 nanometers (nm), including in a range of from about 3 nm to about 11 nm. In one or more embodiments, the second dielectric layer 212 may be deposited using any suitable technique. In some embodiments, the second dielectric layer 212 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

Referring to FIG. 1 and FIG. 3B, in one or more embodiments, at operation 20, the second or outer dielectric layer 212 is recessed to expose the first or inner dielectric layer 210 and forms a recessed region 214 between the adjacent stacks 201 of superlattice structures 205. In one or more embodiments, a portion of the second dielectric layer 212 remains in the opening 207 between the stacks. The second dielectric layer 212 may be removed by any suitable means known to the skilled artisan. In one or more embodiments, the dielectric layer 212 is removed by isotropic etching.

Referring to FIG. 1 and FIG. 3D, in one or more embodiments, at operation 20, the second or outer dielectric layer 212 encloses the first or inner dielectric layer 210 and between the adjacent stacks 201 of superlattice structures 205.

With reference to FIG. 1 and FIG. 3D, at operation 56, an airgap 214 is form on the backside of the device such that the second or outer dielectric layer 212 encloses the airgap 214.

In some embodiments, the methods are integrated such that there is no vacuum break between one or more operations. In one or more embodiments, the method 10 can be integrated such that there is no vacuum break between the nanosheet patterning and formation of the bilayer dielectric wall.

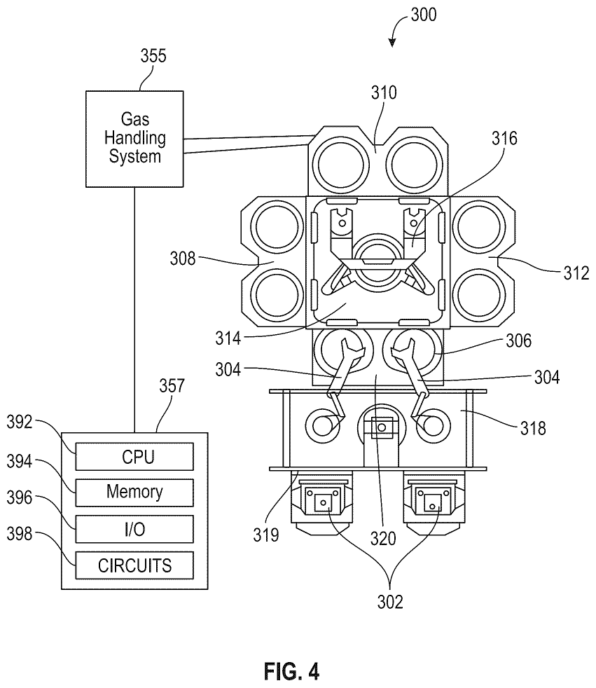

Additional embodiments of the disclosure are directed to processing tools 300 for the formation of the GAA devices, FinFETs, CFETS, and methods described, as shown in FIG. 4. A variety of multi-processing platforms may be utilized. The cluster tool 300 includes at least one central transfer station 314 with a plurality of sides. A robot 316 is positioned within the central transfer station 314 and is configured to move a robot blade and a wafer to each of the plurality of sides.

The cluster tool 300 comprises a plurality of processing chambers 308, 310, and 312, also referred to as process stations, connected to the central transfer station. The various processing chambers provide separate processing regions isolated from adjacent process stations. The processing chamber can be any suitable chamber including, but not limited to, a pre-clean chamber, a deposition chamber, an annealing chamber, an etching chamber, and the like. The particular arrangement of process chambers and components can be varied depending on the cluster tool and should not be taken as limiting the scope of the disclosure.

In the embodiment shown in FIG. 4, a factory interface 318 is connected to the front of the cluster tool 300. The factory interface 318 includes chambers 302 for loading and unloading on a front 319 of the factory interface 318.

The size and shape of the loading chamber and unloading chamber 302 can vary depending on, for example, the substrates being processed in the cluster tool 300. In the embodiment shown, the loading chamber and unloading chamber 302 are sized to hold a wafer cassette with a plurality of wafers positioned within the cassette.

Robots 304 are within the factory interface 318 and can move between the loading and unloading chambers 302. The robots 304 are capable of transferring a wafer from a cassette in the loading chamber 302 through the factory interface 318 to load lock chamber 320. The robots 304 are also capable of transferring a wafer from the load lock chamber 320 through the factory interface 318 to a cassette in the unloading chamber 302.

The robot 316 of some embodiments is a multi-arm robot capable of independently moving more than one wafer at a time. The robot 316 is configured to move wafers between the chambers around the transfer chamber 314. Individual wafers are carried upon a wafer transport blade that is located at a distal end of the first robotic mechanism.

A system controller 357 is in communication with the robot 316, and a plurality of processing chambers 308, 310 and 312. The system controller 357 can be any suitable component that can control the processing chambers and robots. For example, the system controller 357 can be a computer including a central processing unit (CPU) 392, memory 394, inputs/outputs 396, suitable circuits 398, and storage.

Processes may generally be stored in the memory of the system controller 357 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware such as, e.g., an application specific integrated circuit or other type of hardware implementation, or as a combination of software and hardware. The software routine, when executed by the processor, transforms the general-purpose computer into a specific-purpose computer (controller) that controls the chamber operation such that the processes are performed.

In some embodiments, the system controller 357 has a configuration to control the rapid thermal processing chamber to crystallize the template material.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a template deposition chamber and a template crystallization chamber; and a controller connected to the central transfer station and the plurality of process stations, the controller configured to activate the robot to move the wafer between process stations, and to control a process occurring in each of the process stations.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
forming a bilayer dielectric wall in an opening between one or more first channel regions for a first transistor and one or more second channel regions for a second transistor.

2. The method of claim 1, wherein the first transistor and the second transistor are on a substrate, the opening extends at least partially into the substrate, and wherein the bilayer dielectric wall fills the opening.

3. The method of claim 1, wherein the first transistor and the second transistor are selected from gate-all-around transistors, FinFET transistors, or CFET transistors.

4. The method of claim 1, wherein forming the bilayer dielectric wall comprises depositing a liner dielectric layer, and subsequently depositing a core dielectric layer on the liner dielectric layer.

5. The method of claim 4, further comprising recessing a portion of the core dielectric layer in the opening.

6. The method of claim 4, wherein the liner dielectric layer comprises a low-k dielectric material and the core dielectric layer comprises a high-k dielectric material.

7. The method of claim 6, wherein the core dielectric layer is selected from one or more of hafnium oxide (HfOx), hafnium nitride (HfN), aluminum oxide (AlOx), and aluminum nitride (AlN).

8. The method of claim 6, wherein the liner dielectric layer is selected from one or more of silicon carbonitride (SiCN), silicon oxynitride (SiON), silicon oxycarbonitride (SiOCN), and silicon oxycarbide (SiOC).

9. The method of claim 4, further comprising recessing the core dielectric layer to leave a recessed portion of the core dielectric layer in the opening between the one or more first channel regions and the one or more second channel regions.

10. The method of claim 9, further comprising encapsulating the recessed portion of the core dielectric layer to form an encapsulated bilayer dielectric wall between the one or more first channel regions and the one or more second channel regions.

11. The method of claim 10, further comprising removing the encapsulated recessed portion of the core dielectric layer to form an airgap between the one or more first channel regions and the one or more second channel regions.

12. The method of claim 2, further comprising forming a shallow trench isolation (STI) adjacent to the first transistor and the second transistor.

13. The method of claim 4, wherein the core dielectric layer has a first thickness in a range of from about 5 nanometers to about 20 nanometers, and the liner dielectric layer has a second thickness in a range of from about 1 nanometer to about 15 nanometers.

14. The method of claim 1, wherein the bilayer dielectric wall is between a first superlattice structure that comprises the one or more first channel regions for the first transistor and a second superlattice structure that comprises the one or more second channel regions for the second transistor.

15. A method of forming a semiconductor device, the method comprising:
depositing a first dielectric layer between a first superlattice structure and on a second superlattice structure on a top surface of a substrate, the first superlattice structure and the second superlattice structure comprising a plurality of horizontal channel layers and a corresponding plurality of semiconductor material layers alternatingly arranged in a plurality of stacked pairs and separated by an opening;
depositing a second dielectric layer on the first dielectric layer to form a bilayer dielectric wall;
recessing the second dielectric layer to leave a recessed portion of the second dielectric layer in the opening between the first superlattice structure and the second superlattice structure; and
encapsulating the recessed portion of the second dielectric layer to form an encapsulated bilayer dielectric wall between the first superlattice structure and the second superlattice structure.

16. The method of claim 15, further comprising removing the encapsulated recessed portion of the second dielectric layer to form an airgap between the first superlattice structure and the second superlattice structure.

17. The method of claim 15, wherein the first dielectric layer comprises a low-k dielectric material selected from one or more of silicon carbonitride (SiCN), silicon oxynitride (SiON), silicon oxycarbonitride (SiOCN), and silicon oxycarbide (SiOC), and wherein the second dielectric layer comprises a high-k dielectric material selected from one or more of hafnium oxide (HfOx), hafnium nitride (HfN), aluminum oxide (AlOx), and aluminum nitride (AlN).

18. The method of claim 15, wherein the first dielectric layer has a second thickness in a range of from about 1 nanometers to about 15 nanometers, and wherein the second dielectric layer has a first thickness in a range of from about 5 nanometers to about 20 nanometers.

19. The method of claim 15, further comprising
forming a shallow trench isolation (STI) on the encapsulated bilayer dielectric wall and on the first superlattice structure and the second superlattice structure;
forming a second layer of second dielectric layer on the shallow trench isolation (STI);
recessing the shallow trench isolation (STI);
exposing the plurality of horizontal channel layers and the corresponding plurality of semiconductor material layers;
forming a plurality of source trenches and a plurality of drain trenches adjacent to the first superlattice structure and the second superlattice structure;
forming a source region and a drain region;
forming a replacement metal gate;
forming a contact to transistor and a contact to gate in electrical contact with the source region and the drain region; and
forming a metal line.

20. The method of claim 19, further comprising recessing the first dielectric layer of the encapsulated bilayer dielectric wall prior to forming the source region and the drain region.
